(19) United States
(12) Patent Application Publication
(10) Pub. No.: US 2015/0017747 A1
(43) Pub. Date: Jan. 15, 2015

(54) METHOD FOR FORMING A SOLAR CELL WITH A SELECTIVE EMITTER

(71) Applicant: REC SOLAR PTE. LTD., Singapore (SG)

(72) Inventors: Jenny Lam, Singapore (SG); Rob Steeman, Singapore (SG)

(21) Appl. No.: 14/376,280

(22) PCT Filed: Feb. 1, 2013
(86) PCT No.: PCT/IB2013/000132

§ 371 Date: Aug. 1, 2014

Related U.S. Application Data
(60) Provisional application No. 61/594,155, filed on Feb. 2, 2012.

(30) Foreign Application Priority Data
Feb. 2, 2012 (GB) 1201881.8

(51) Int. Cl. H01L 31/18; H01L 21/66

(52) U.S. Cl. CPC H01L 31/1864; H01L 22/12
USPC 438/14; 438/98

(57) ABSTRACT

A method for producing a solar cell with a selective emitter is disclosed. A semiconductor substrate (1) is provided. A layer (3) of dopant source material with a dopant type opposite to the dopant type of the substrate (1) is formed at a surface of the substrate (1). By applying heat to the layer (3), a homogeneous lightly doped emitter region (5) is formed. In a first lasering step, selective heavily doped emitter regions (11) are formed by applying laser light (7) to contact surface areas (9). Optionally, the layer (3) is subsequently removed and an additional dielectric layer (15) is applied to the front side of the substrate (1). In a second lasering step, the layer (3) or the layer (15) are locally removed by applying laser light (21) to the contact surface areas (9), thereby locally exposing the surface of the substrate (1). In the locally exposed contact surface areas (9), metal contacts (23) are finally formed, using for example metal-plating techniques. Using two different lasering steps for laser doping, on the one hand, and laser removal for forming the metallization mask, on the other hand, allows optimizing each of the lasering steps independently from each other, thereby enabling improvements for the processing and resulting solar cell.

### RELATED APPLICATIONS

The present application claims the priority of the British patent application no. 1201881.8, filed on Feb. 2, 2012 as well as U.S. provisional patent application No. 61/594,155 filed on Feb. 2, 2012, whose content is incorporated into this document by reference.

### FIELD OF THE INVENTION

The present invention relates to a method for forming a solar cell with a selective emitter.

### TECHNICAL BACKGROUND

Solar cells are used to convert sunlight into electricity using a photovoltaic effect. A general object is to achieve high conversion efficiency and high reliability balanced by a need for low production costs.

One approach of increasing the conversion efficiency of a solar cell is to provide the solar cell with what is known as a “selective emitter”.

Generally, in a solar cell, a semiconductor substrate is provided with a doping of a base type and at a surface of such semiconductor substrate an emitter layer with an opposite doping is formed.

In homogeneously doped emitters a trade-off with respect to the doping concentration has to be made as e. g. low doping concentration may improve a spectral response of the solar cell but may result in increased contact resistance of emitter metal contacts whereas, inversely, high doping concentration reduces contact resistance but deteriorates the spectral response.

With the selective emitter approach, only partial regions corresponding to contact regions in which metal contacts adjoin the semiconductor surface are heavily doped, thereby reducing contact resistance, while intermediate regions are only lightly doped thereby keeping the spectral response high in these regions.

U.S. Pat. No. 6,429,037 B1 to S. Wenham discloses a self-aligning method for forming a selective emitter and metallization in a solar cell.

An alternative approach is disclosed by U. Jaeger et. al.:“Selective emitter by laser doping from phosphor silicate glass”, presented at the 24^{th} European PV Solar Energy Conference and Exhibition, 21-25 September 2009, Hamburg, Germany.

### SUMMARY OF THE INVENTION

It is an object of the present invention to provide an alternative method of producing a solar cell with a selective emitter. Particularly, such method should be able to be implemented economically and in an industrial scale. The produced solar cells should have both high conversion efficiency and high long-term reliability.

Such objects may be met with the subject-matter of the independent claims. Advantageous embodiments are defined in the dependent claims.

According to an aspect of the present invention, a method for producing a solar cell is proposed. The method comprises the following steps, preferably in the indicated order: (a) providing a semiconductor substrate doped with a base dopant type; (b) forming a layer of dopant source material of an emitter dopant type opposite to the base dopant type at a surface of the semiconductor substrate; (c) applying heat to the layer of dopant source material to thereby diffuse dopants from the layer of dopant source material into an adjacent surface area of the semiconductor substrate for forming a homogeneous lightly doped emitter region; (d) in a first lasering step, locally applying laser light to contact surface areas of the semiconductor substrate surface to thereby additionally generate electrically active dopants in the contact surface areas of the semiconductor substrate for forming a selective heavily doped emitter region; (e) in a second lasering step, locally applying laser light to at least part of the contact areas of the semiconductor substrate surface to thereby locally remove at least one of the layer of dopant source material and a dielectric layer formed at the surface of the semiconductor substrate to thereby locally expose the surface of the semiconductor substrate in the contact surface areas, wherein in the second lasering step other laser characteristics apply than in the first lasering step; and (f) forming metal contacts which electrically contact the surface of the semiconductor substrate in the locally exposed contact surface areas.

A gist of the proposed silicon solar cell may be seen as based on the following ideas and recognitions:

While with prior art approaches for solar cells with a selective emitter, high conversion efficiencies have been shown, particularly at a laboratory production scale, it has been observed that, in such prior art approaches, difficulties may occur during solar cell production which may result in e. g. reduced long-term reliability of the produced solar cell or in increased production efforts.

For example, in the above-mentioned prior art approach proposed by Wenham, only one single lasering step is used during production of one-side structures of the solar cell. In this one lasering step, introduction of locally added dopants for preparing the heavily doped areas of the selective emitter is performed simultaneously with a step of opening a dielectric layer for exposing the surface of the semiconductor substrate in the surface area in order to be able to metalize that front-side in these surface areas subsequently. However, while such using of a single lasering step enables self-aligning of the heavily doped areas with the metal contacts to be applied subsequently, it has now been observed that, in such processing approach, for example adhesion problems of the metal contacts prepared by plating techniques may occur.

It is presently believed that one possible explanation for such adhesion problems may be seen in the fact that, as only one single lasering step is applied, such lasering step cannot be optimized for both purposes, the selective laser doping on the one hand and the local removal of a dielectric layer on the other hand.

The method proposed herein therefore applies two separate lasering steps in which the laser characteristics differ from one another for example with respect to laser light intensity, laser light frequency, laser light focusing, irradiation duration, etc. Therein, a first lasering step is used for generating the selective heavily doped emitter regions of the selective emitter by laser doping and a second lasering step is used for locally removing a layer previously deposited on top of the semiconductor substrate in order to thereby locally expose the surface of the semiconductor substrate such that, subsequently, metal contacts may be formed at such exposed contact surface areas.

Furthermore, it is presently believed that for example in the approach proposed by Wenham, typically a phosphorous diffusion source is spinned-on or sprayed-on on top of a dielectric layer deposited on top of the lightly doped emitter surface and, subsequently, dopants are introduced into the underlying semiconductor substrate using laser doping. A risk is seen that in such laser doping approach, atomic species other than the dopant species, from the dielectric layer may be incorporated in the doped regions, such elements possibly inhibiting good adhesion of metal contacts to be prepared subsequently by plating techniques.

In the method proposed herein it is therefore proposed to use for example a different dopant source material such as e. g. phosphorous silicate glass (PSG) as a dopant source material.

Furthermore, as, according to the present proposed method, layers overlying the semiconductor substrate are locally removed in the contact surface areas using a separate lasering step, such second lasering step may be specifically optimized in order to prevent any incorporation of atomic species of the dielectric layer in the doped regions.

In the following, possible features and advantages of embodiments of the proposed solar cell production method are explained in detail.

The semiconductor substrate provided for the proposed production method may be any type of substrate. For example, silicon wafers or silicon thin-films may be used. The silicon may be e.g. mono-crystalline or multi-crystalline. The base doping of the semiconductor substrate may be n-type or p-type. For example, homogeneous phosphorous or boron doping, respectively, may be provided.

The layer of dopant source material may be any layer in which a dopant of an opposite type to the base dopant type is included, preferably in a homogeneous distribution. Preferably, the dopant source material is phosphorous silicate glass (PSG). Such PSG may be formed e. g. in a POCl₃ diffusion step in which the semiconductor substrate is treated in a POCl₃ atmosphere at elevated temperatures. The PSG comprises a high content of phosphorous dopants, which, upon applying heat to the layer of dopant source material, may diffuse from this layer into the adjacent surface of the semiconductor substrate. Thereby, a homogeneous lightly doped emitter region may be prepared at such substrate surface.

After generating such homogeneous doped emitter regions, selective heavily doped emitter partial regions are prepared by laser doping in a first lasering step. Therein, laser light of suitable characteristics is locally applied to the dopant source material layer in order to e.g. locally additionally introduce dopants from such layer to the semiconductor substrate in contact surface,areas in which, subsequently, metal contacts are to be formed. During such laser doping, the energy of the applied laser light may be high enough to temporarily liquefy at least one or preferably both of the dopant source material layer and a superficial region of the semiconductor substrate. Thereby, additional dopants may be incorporated into such local areas of the semiconductor substrate surface at high rate thereby resulting in locally increased dopant concentration. Alternatively, dopants which have already been introduced previously into the contact surface areas but which have been electrically inactive may be activated by locally applying energy during the first lasering step such that active dopant concentration may be locally increased.

After such first lasering step for the laser doping, the semiconductor substrate may be removed from a lasering apparatus used for such lasering step. Optionally, the semiconductor substrate may then be processed further using for example different processing apparatuses. During such further processing, for example rear-side structures of the solar cell may be generated at a surface of the solar cell opposite to the surface carrying the selective emitter. Then, at a later stage of the processing sequence, the semiconductor substrate may be installed again in a lasering apparatus which may be identical or different to the lasering apparatus used for the first lasering step. Before performing the second lasering step, the semiconductor substrate may be aligned, i. e. the semiconductor substrate may be positioned relative to the lasering apparatuses, such that, in the subsequent second lasering step, laser light is applied such that the surface of the semiconductor substrate is locally exposed by the application of the laser light in the same contact areas which, in the first lasering step, have been heavily doped.

It may be essential for the resulting solar cell that the semiconductor substrate is aligned before performing the second lasering step in order to be able to specifically locally remove any overlying layer from the semiconductor substrate in exactly the regions which, in the first lasering step, have been selectively heavily doped, As, in a subsequent processing step, metal contacts are to be formed selectively in the contact surface areas locally exposed during the second lasering step, it may be necessary to co-align such metal contacts with the locally heavily doped emitter regions prepared in the first lasering step in order to ensure low contact resistances.

For example, the semiconductor substrate may be aligned using an optical alignment device. Such optical alignment device may be adapted to detect e. g. features of the semiconductor substrate optically in order to then enable alignment of the semiconductor substrate.

For example, the optical alignment device may detect a position of the semiconductor substrate relative to the lasering device. Specifically, the alignment device may first detect a position of the semiconductor substrate relative to the lasering device used for the first lasering step and store such position information. Then, before the second lasering step, an alignment device may again detect a current position of the semiconductor substrate relative to the lasering device used for the second lasering step and may then adapt either the position of the semiconductor substrate or the positioning of the laser device, i. e. the direction in which the lasering device emits laser light, such that, during the second lasering step, laser light is applied in alignment with the contact surface areas heavily doped during the first lasering step.

Alternatively, the optical alignment device may directly detect positions of contact areas which have been additionally doped during the first lasering step. In such alignment process, benefit may be taken from the fact that, during the first lasering step, optical characteristics may be slightly altered in the contact surface areas and these optical alterations may be detected by the alignment device. Upon detection of the contact surface areas, a lasering device may be controlled such that laser light is only applied in alignment with the contact surface areas.

In an embodiment of the present invention, the layer of dopant source material is removed after the first lasering step and a dielectric layer serving as a surface passivation layer, a metallization mask and/or an antireflection layer is formed at the semiconductor substrate surface prior to the second layering step. Therein, the dopant source material such as e. g. the phosphorous silicate glass may be completely removed from the semiconductor substrate and the substrate surface may then be covered by a dielectric layer such as e. g. a silicon nitride (SiN) layer.

As a further alternative, the dopant source material may remain at the surface of the semiconductor substrate, i.e. is not removed after the first lasering step, and, additionally, a dielectric layer is deposited on top of the remaining layer of dopant source material. This additional dielectric layer may serve e.g. as a surface passivation layer, a metallization mask and/or an antireflection layer.

Depending on the specific processing sequence optionally including removing the dopant source material layer and/or depositing an additional dielectric layer, in the second lasering step the laser light may locally remove each of a previously deposited dopant source material layer and a previously deposited dielectric layer existing at the substrate surface at this stage of the processing sequence in order to locally expose the substrate surface.

While the characteristics of the dopant source material layer may be optimized for laser doping, such dopant source material layer may not necessarily have optimized characteristics for remaining on a resulting solar cell. Therefore, such dopant source material layer may be removed and a dielectric layer having optimized characteristics for specific purposes may be applied instead. Alternatively, an additional dielectric layer may be deposited on top of the dopant source material layer. For example, a silicon nitride layer deposited using e. g. PECVD (plasma enhance chemical vapor deposition) may serve as a highly surface passivating layer, thereby increasing the conversion efficiency of this solar cell. Furthermore or alternatively, such dielectric layer may serve as a metallization mask during subsequent formation of the metal contacts. Furthermore or as a further alternative, the dielectric layer may be applied in a suitable layer thickness such as to serve as an antireflection coating for the resulting solar cell.

In a preferred embodiment of the invention, the metal contacts are formed using metal plating techniques. Such plating techniques may comprise galvanic plating or electroless plating, wherein metal is deposited from a metal containing plating solution to the exposed contact surface areas of the semiconductor substrate.

Typically, such plating techniques allow for high quality metal contacts with a low contact resistance to the semiconductor substrate and with low series resistances. The width of metal contacts formed by such techniques is mainly determined by the width of the exposed contact surface areas, i. e. by characteristics of the laser light applied during the second lasering step for locally removing any overlying layer which, in areas adjacent to the contact surface areas, serves as a metallization mask. Accordingly, the combination of laser removal of a metallization mask layer and using metal plating techniques allows for preparing very fine metal contacts having contact widths of for example well below 100 micrometers, preferably below 50 micrometers.

For example, in the first lasering step, laser light may be applied such that additional dopants are introduced along a line, the line having a width of less than 100 micrometers. In other words, using the first lasering step, linear selective heavily doped emitter regions may be prepared with a very narrow width. Between neighbouring linear contact surface areas, a broad region of a homogeneously lightly doped emitter may exist, such region being substantially broader than the contact surface areas, for example in the range of 1 to 3 millimetres. Such narrow contact surface areas in combination with large lightly doped emitters in between may result in improved spectral response for the solar cell.

In the second lasering step, the surface of the semiconductor substrate in the contact surface areas may also be exposed along a line, wherein this second line superimposes the first line and has a width being equal or smaller than the width of the first line, i. e. when the width of the heavily doped contact surface areas. Using such smaller width for the exposed surface area created by the second lasering step may, on the one hand, enable formation of very narrow metal contacts. Such narrow metal contacts may result in reduced shadowing losses. On the other hand, removing overlying layers only along very narrow lines in the second lasering step may simplify alignment of the resulting exposed contact areas with the heavily doped areas created during the first lasering step.

It may be noted that possible features and advantages of embodiments of the present invention are described herein mainly with respect to the proposed method for preparing a solar cell but also partly with respect to the resulting solar cell. One skilled in the art will recognize that the different features may be suitably combined and features of the solar cell may be realized in a corresponding manner in the preparation method and vice versa in order to implement further advantageous embodiments and realize synergetic effects.

Furthermore, one skilled in the art will realize that the complete production process may comprise further steps and the solar cell may have more features than described herein. For example, the proposed method may be part of a method for preparing an entire solar cell, such method comprising various additional method steps such as diffusion steps, passivation steps, metallization steps, etc. The solar cell may comprise differently doped regions, dielectric layers at surfaces thereof as anti-reflection coating, surface passivation, etc. and additional electrical contact structures on a front and/or rear side of the solar cell substrate, to mention only a few examples.

### BRIEF DESCRIPTION OF THE DRAWINGS

In the following, features and advantages of embodiments of the present invention are described with respect to the enclosed drawings. Therein, neither the description nor the drawings shall be interpreted as limiting the invention.

FIG. 1 shows steps of a method for producing a solar cell according to an embodiment of the present invention.

The drawings are schematically and not to scale. Same or similar features are designated with same reference signs throughout the drawings.

### DESCRIPTION OF PREFERRED EMBODIMENTS

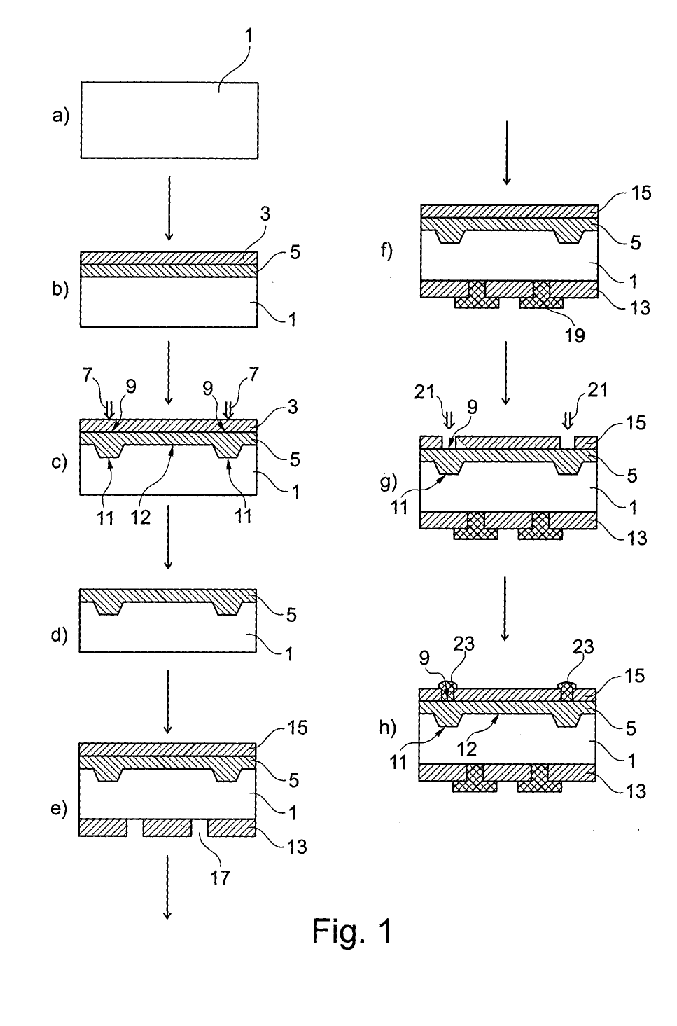

Referring to FIG. 1, a processing sequence for a method of producing a solar cell in accordance with an embodiment of the present invention is described.

In step (a), a semiconductor substrate 1 is provided as a silicon wafer having a homogeneous p-type base doping. The semiconductor substrate 1 may be pre-treated e.g. with saw-damage removal etch and/or polishing of its backside.

In step (b), a layer 3 of dopant source material is formed. In the specific example, this layer 3 is formed as a phosphorous silicate glass during a POCl₃ diffusion step, in which the semiconductor substrate 1 is held in a POCl₃ atmosphere at high temperatures of e. g. 800 to 900 degrees Celsius for a duration of e. g. 10 to 90 minutes.

Simultaneously with the formation of the layer 3 of dopant source material, dopants from such layer 3 diffuse into the front surface of the semiconductor substrate 1 due to the applied heat thereby forming a homogeneous lightly doped emitter region 5. This lightly doped emitter region 5 may be generated for example with a sheet resistance of more than 80 Ohm/square, preferably more than 100 Ohm/square, such as to create an emitter for the solar cell having a good spectral response.

In the next step (c), the semiconductor substrate 1, together with the phosphorous silicate glass serving as a dopant source material layer 3, is arranged within a lasering apparatus. In this lasering apparatus, laser light 7 is locally applied to contact surface areas 9 of the surface of the semiconductor 1.The intensity of the laser light 7 is selected such that the dopant source material layer 3 is temporarily locally liquefied or partly evaporated. In such state, additional dopants are introduced into the semiconductor substrate at the contact surface areas 9. Also, additional phosphor, already present in the emitter, but not electrically active, may be activated by the exposure of the wafer to laser light. Selective heavily doped emitter regions 11 having a doping concentration being substantially higher than the doping concentration in intermediate regions 12 result. For example, in the selective heavily doped emitter region 11, a sheet resistance may be lower than 70 Ohm/square, preferably lower than 30 Ohm/square and more preferably lower than 15 Ohm/square. The width of the laser beam 7 may be such that the resulting heavily doped emitter regions 11 have a width of e. g. less than 100 micrometers, preferably less than 50 micrometers, and more preferably less than 30 microns.

In step (d), the dopant source material layer 3 is removed by etching such that the entire surface of the emitter 5 is exposed. For example, phosphorous silicate may be removed with a HF-containing etch solution. Additionally, the backside of the substrate 1 may be submitted to a single-side etch in order to remove any potential residual emitter on the backside due to wrap around in the diffusion process.

With respect to step (e) of FIG. 1, the result of several independent processing steps is shown.

A dielectric layer 13 is deposited on the back-side of the semiconductor substrate 1. This layer may comprise for example a stack of an Al₂O₃ layer and a SiN layer.

On the front-side of the semiconductor substrate 1, a dielectric layer 15 is deposited. This dielectric layer 15 may be, for example, a high-quality silicon nitride (SiN) layer which, for the resulting solar cell, may serve as a surface passivation of the substrate's front-side surface. Furthermore, the dielectric layer 15 may serve as a masking layer during subsequent metal contact formation and, possibly, as an antireflection coating.

The back-side dielectric layer 13 may be locally opened using e. g. laser removal such that dots 17 of exposed areas of the back-side of the semiconductor substrate 1 are prepared.

In step (f), back-side contacts 19 are prepared using locally screen printing of a silver (Ag) containing paste and/or of an aluminum (Al) containing paste over the dots 17, subsequently drying the paste and finally firing the paste to thereby form the back-side contacts 19.

In step (g), the front-side dielectric layer 15 is locally removed in a second lasering step by locally applying laser light 21 at least to part of the contact surface areas 9 of the surface of the semiconductor substrate 1. Therein, characteristics of the applied laser beam 21 are selected such that the dielectric layer 15 is locally removed and the surface of the semiconductor substrate 1 is locally exposed at the contact surface areas 9. The width of the laser beam 21 is such that the exposed areas are narrower than the width of the heavily doped emitter regions 11 formed in the first lasering step.

It may be noted that lasering characteristics may differ between the first and the second lasering step. Generally, laser-material interaction depends on several physical parameters such as wavelength, pulse energy and pulse duration of the applied laser light, besides optical and thermodynamics properties of the material.

In the first lasering step, laser wavelengths in the IR spectral range, e.g. at 1064 nm, and in the visible spectral range, e.g. at 532 nm, may be typically chosen, where silicon is highly absorbing. Laser wavelength in the visible region is more favorable in creating heavily doped emitter regions due to a shorter optical penetration depth that aids in limiting laser-induced crystal defects. These defects may act as recombination centers and degrade solar cell performance consequently. The typical laser pulse duration is in the nanosecond regime and laser pulse energy is optimized to limit laser melting of e.g. a textured silicon surface.

In the second lasering step, laser wavelengths in the IR spectral range, e.g. at 1064 nm, in the visible spectral range, e.g. at 532 nm and in the UV spectral range, e.g. at 355 nm, may be effective in selective dielectric laser ablation. It may be important to employ a suitable pulse duration with the selected laser wavelength. In a solar cell fabrication process, local removal of dielectric layer without melting the underlying heavily doped emitter regions may be crucial e.g. in creating a good contact surface for subsequeent electroplating process. Laser melting of the heavily doped emitter regions may be unfavorable as it may result in dopant redistribution in silicon as well as incoporation of contaminants such as oxygen, nitrogen and etc. To circumvent this issue, ultrafast laser pulses with pulse durations in pico- and femtoseconds may be employed particularly for laser wavelegths in the IR and visible spectral ranges where the laser energy is absorbing mainly in the dielectric layers via non-linear absorption effects. In non-linear absorption, laser pulses may be short enough to reach peak power intensity that break lattice bounds of the dielectric layers with virtually no heat transfer and silicon melting. On the other hand, as silicon nitride is highly absorbing in the UV spectral range, pulse durations in the nanoseconds and picoseconds timescale may be employed to minimize melting of the underlying heavily doped emitter regions with local removal of the dielectric layer.

Finally, in step (h), front-side metal contacts 23 are formed using metal-plating techniques. Therein, optionally, any nitrides formed at the surface area exposed by the second lasering step may be removed by an etching step. Such etching may also serve for removing a local lasering damage in the semiconductor substrate. Then, metal is deposited from a plating solution at the contact surface areas 9 exposed during the previous second lasering step, while, in intermediate regions 12, the overlying front-side dielectric layer 15 serves as a plating mask.

The plating technique used for forming the front-side metal contacts 23 may be galvanic or electroless and may comprise a sequence of sub-steps. For example, first, nickel may be deposited in direct contact with the exposed surface of the silicon wafer forming the semiconductor substrate 1. In a subsequent anneal step at elevated temperatures, a nickel silicide may be formed. Such silicide may serve for improved mechanical adhesion as well as reduced electrical contact resistance between the metal contacts 23 and the semiconductor substrate 1. Excessive nickel may subsequently be removed in an etching step. A further homogeneous nickel layer may be deposited in a “flash”-plating step before a thick layer of copper is plated onto the nickel layer in order to form the core of the metal contacts 23 thereby providing contacts with very low series resistance.

Finally, it should be noted that the term “comprising” does not exclude other elements or steps and the “a” or “an” does not exclude a plurality. Also elements described in association with different embodiments may be combined. It should also be noted that reference signs in the claims should not be construed as limiting the scope of the claims.

### List of Reference Signs

1 semiconductor substrate
3 Layer of dopant source material
5 homogeneous lightly doped emitter region
7 laser light of first lasering step
9 contact surface areas
11 selective heavily doped emitter regions
12 intermediate lightly doped regions
13 rear-side dielectric layer
15 front-side dielectric layer
17 exposed back-side dots
19 back-side metal contacts
21 laser light of second lasering step
23 front-side metal contacts

1. A method for producing a solar cell, comprising the steps of:
a) providing a semiconductor substrate doped with a base dopant type;
b) forming a layer of dopant source material of an emitter dopant type opposite to the base dopant type at a surface of the semiconductor substrate;
c) applying heat to the layer of dopant source material to thereby diffuse dopants from the layer of dopant source material into an adjacent surface area of the semiconductor substrate for forming a homogeneous lightly doped emitter region;
d) in a first lasering step, locally applying laser light to contact surface areas of the semiconductor substrate surface to thereby additionally generate electrically active dopants in the contact surface areas of the semiconductor substrate for forming a selective heavily doped emitter region;
e) in a second lasering step, locally applying laser light to the contact areas of the semiconductor substrate surface to thereby locally remove at least one of the layer of dopant source material and a dielectric layer formed at the surface of the semiconductor substrate to thereby locally expose the surface of the semiconductor substrate in the contact surface areas,
wherein in the second lasering step other laser characteristics apply than in the first lasering step;
f) forming metal contacts which electrically contact the surface of the semiconductor substrate in the locally exposed contact surface areas.

2. The method of claim 1, wherein, after the first lasering step, the semiconductor substrate is removed from a lasering apparatus and further processed, and wherein, before the second lasering step, the semiconductor substrate is installed in a lasering apparatus and aligned such that, in the second lasering step, the laser light is applied such that the surface of the semiconductor substrate is exposed in the same contact surface areas which have been heavily doped in the first lasering step.

3. The method of claim 2, wherein the semiconductor substrate is aligned using an optical alignment device.

4. The method of claim 3, wherein the optical alignment device detects a position of the semiconductor substrate relative to the lasering device.

5. The method of claim 3, wherein the optical alignment device detects positions of contact surface areas which have been additionally doped in the first lasering step.

6. The method of claim 1, wherein between the first lasering step and the second lasering step, the layer of dopant source material is removed and a dielectric layer serving at least as one of a surface passivation layer, a metallization mask and an antireflection layer is formed at the semiconductor substrate surface.

7. The method of claim 1, wherein, in step (f), the metal contacts are formed using metal plating techniques.

8. The method of claim 1, wherein, in the first lasering step, laser light is applied such that additional dopants are introduced along a line, the line having a width of less than 100 μm.

9. The method of claim 1, wherein, in the first lasering step, laser light is applied such that additional dopants are introduced along a first line, and wherein, in the second lasering step, the surface of the semiconductor substrate in the contact surface areas is exposed along a second line, wherein the second line superimposes the first line and has an equal or smaller width than the first line.

10. The method of claim 1, wherein the dopant source material is a phosphorous silicate glass.
